(19) United States
(12) Patent Application Publication
(10) Pub. No.: US 2025/0088145 A1
(43) Pub. Date: Mar. 13, 2025

(54) LIGHT ENERGY STORAGE AND USE

(71) Applicant: DRACULA TECHNOLOGIES, VALENCE (FR)

(72) Inventors: Brice CRUCHON, GUILHERAND GRANGES (FR); Alexis HARDOUIN, VALENCE (FR); Sadok BEN DKHIL, VALENCE (FR); Jérôme VERNET, Montellier (FR)

(21) Appl. No.: 18/405,832

(22) Filed: Jan. 5, 2024

Related U.S. Application Data
(60) Provisional application No. 63/581,270, filed on Sep. 7, 2023.

(51) Int. Cl. H02S 40/38; H01G 11/84; H10K 39/00; H10K 71/13

(52) U.S. Cl. CPC H02S 40/38; H01G 11/84; H10K 39/601; H10K 71/135

(57) ABSTRACT

The present invention relates to a light energy storage and use, to Inkjet-printed flexible autonomous energy source and storage in a single device, and more generally to photovoltaic devices. The present invention relates also to a light energy storage device comprising an organic photovoltaic (OPV) module, a thin film supercapacitor (SC) for the storage of an electric energy generated by the photovoltaic module and a control means; and its process of manufacturing.

### CROSS-REFERENCE TO RELATED APPLICATIONS

The present application claims priority to U.S. Provisional Application No. 63/581,270 filed with the United States Patent and Trademark Office on Sep. 7, 2023 and entitled “LIGHT ENERGY STORAGE AND USE,” which is incorporated herein by reference in its entirety for all purposes.

### TECHNICAL FIELD

The present invention relates to a light energy storage and use, to Inkjet-printed flexible autonomous energy source and storage in a single device, and more generally to photovoltaic devices. The present invention relates also to a light energy storage device comprising an organic photovoltaic (OPV) module, a thin film supercapacitor (SC) for the storage of an electric energy generated by the photovoltaic module and a control means, and its process of manufacturing.

### TECHNICAL BACKGROUND

Many devices run on electrical energy, and to make them mobile, a number of them have been fitted with batteries. However, this solution has certain limitations, such as the need for regular battery replacement or the need to increase the size of the devices. Further, the negative environmental impacts of these batteries' replacements are strong.

There are also devices that can be recharged using solar energy. However, these solutions also have certain limitations, including the need for exposure to solar-rays and therefore for resistance to external conditions.

There is therefore a strong need for small devices that can be recharged under indoor radiations, i.e., generally less than or equal to 1000 lux, and still have good autonomy. There is also a strong need for small and more discreet devices with less negative environmental impacts.

The prior art devices are combinations of pre-existing elements that requires specific connectivity between the elements. This connectivity negatively impacts the performance of the devices and the flexibility of said prior art devices. Also, these prior art devices need more space and are difficult to miniaturize which is mainly linked to the volume occupied by the storage element, such as batteries or supercapacitors, and connection cables. Prior art devices have reduced adaptability with target product.

### DETAILED DESCRIPTION OF THE INVENTION

The inventors have developed a lightweight energy storage device making it possible to reduce the overall cost in terms of manufacture and use and to reduce energy consumption. This lightweight energy storage device makes it possible to do away with heavy and sometimes bulky batteries, and thus to reduce the economic and negative environmental impact of these batteries. This solution also makes it possible to reduce the steric bulk of the device. In addition, the light energy storage device according to the invention can operate under indoor radiation, i.e., generally less than or equal to 1000 lux, and still have good autonomy.

In particular, the inventors have developed a new light energy storage device comprising, in a single assembly, an organic photovoltaic (OPV) module and a thin film supercapacitor (SC).

The light energy storage device according to the invention, integrating a control means, comprises commercially available non-toxic materials and is manufactured with a cost-efficient inkjet printing technique in sheet-to-sheet processing.

In the present description “control means” means any electronic device specialized in controlling the operating voltage and charge of the thin film SC, which is necessary to prevent the phenomenon of “self-discharging”, i.e. the involuntary loss of the energy stored in the thin film SC by parasitic processes. The basic idea of the control means is to convert the voltage obtained by the OPV module so that it can charge the SC. For example, control means may be selected from PMIC AEM10941 (commercial reference) from company E-peas (Belgium) (OPV module input voltage range: 50 mV to 5 V; Storage output voltage range: 1.2 V to 4.5 V) or the voltage supervisor SPV1050 from company STmicroelectronics (French) (OPV module input voltage range: 150 mV to 18 V; Storage output voltage range: 2.6 V to 5.3 V) or any equivalent known by the skilled person in the art.

The integration of an OPV module, a thin film SC and a control means in a single device according to the present invention results advantageously in a flexible, fully autonomous, economic energy source.

In the present description “OPV module” means any suitable module harvesting the light energy, preferably the indoor light energy, to charge a storage means with electric energy, preferably a thin film SC. For example, OPV module may be selected from one of the examples of US patent application US202017787291 (PCT/FR2020/052623) (ref. 1).

In the present description “thin film SC” means any thin film capable of storing electric energy and providing this electric energy (electricity) to an external load or an ultra-capacitor. According to the present invention, preferably, the thin film SC comprises three layers: a current collector, an electrode and an electrolyte.

For example, the current collector, or first layer, may be made of silver. For example, for inkjet printing, it may be selected from “DM-SIJ-3200” from company Dycotec (United Kingdom) or any equivalent known by the skilled person in the art. For example, for screen printing, it may be selected from “HPS-FG57B” from company Novacentrix (United States of America); “HPS-FG32” from company Novacentrix (United States of America); “Saral Silver 700” from company Saralon (Germany) or any equivalent known by the skilled person in the art.

For example, the electrode, or second layer, may be made of carbon black. For example, for inkjet printing, it may be selected from “JR-700HV” from company Novacentrix (United States of America) or any equivalent known by the skilled person in the art. For example, for screen printing, it may be selected from “HPR-059” from company Novacentrix (United States of America); “Saral Carbon 700A” from company Saralon (Germany) or any equivalent known by the skilled person in the art.

For example, the electrolyte, or third layer, may be prepared according to the protocol published in the ECS Transactions, 2018, 86 (14) 163-178. doi: 10.1149/08614.0163ecst, (ref 2); in the Journal of Power Sources, 330, 2016, 92-103. doi:10.1016/j.jpowsour.2016.08.14, (ref 3); Jeong, Jaehoon et al., Ink-Jet Printable, Self-Assembled, and Chemically Crosslinked Ion-Gel as Electrolyte for Thin Film, Printable Transistors. Advanced Materials Interfaces. 2019, 1901074. doi:10.1002/admi.201901074, (ref 4); or Delannoy, P.-E. et al., 2015, Toward fast and cost-effective ink-jet printing of solid electrolyte for lithium microbatteries. Journal of Power Sources. 2015, 274, 1085-1090. doi:10.1016/j.jpowsour.2014.10.164 (ref 5).

According to the present invention, the thin film SC may further comprise an oxygen scavenger, preferably and advantageously in the electrolyte layer (third layer). For example, this oxygen scavenger may be “TPP” (triphenylphosphine) (ref: t84409—25 g) from company Sigma Aldrich (United States of America) or any equivalent known by the skilled person in the art.

Significant competitive advantages of this invention are the specific structure of the device, with a very thin and lightweight structure, the integration of the thin film SC and the control means on the same substrate, for example a foil, and a reduced manufacturing cost in mass volumes, with regard to the prior art devices. Indeed, the integration of the thin film SC and the control means saves space, improves reliability and reduces overall cost of the light energy storage device, particularly indoor light energy storage device. In addition, flexible inkjet printing process enables easier variation of OPV module and thin film SC shape according to application requirements compared to competitive technologies.

The invention provides a light energy storage device comprising an organic photovoltaic (OPV) module and a thin film supercapacitor (SC) for the storage of an electric energy generated by the OPV module, said device comprising:
a) at least a first and a second substrates and optionally an intermediate substrate, made of glass or a polymer material,
b) one OPV module comprising, on a surface of the first substrate, one OPV cell, said OPV cell comprising:
   i) a transparent conductive cathode layer covering said surface of the first substrate,
   ii) a first interfacial metallic oxide-based nanoparticle or organic layer covering said cathode layer,
   iii) a photovoltaic active layer covering said first interfacial layer, and
   iv) a second interfacial layer comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of between 100 nm and 400 nm;
   wherein each layer i) to iv) being printed by inkjet printing;
c) a thin film SC printed on the said surface of said first substrate or on a surface of the intermediate substrate, by digital inkjet printing;
d) a control means, said control means being fixed on the same surface and substrate as the thin film SC with a conductive glue; and
e) one conductive printed by inkjet printing and linking the OPV module, the thin film SC and the control means, and allowing the transfer of the electric energy generated by the OPV module to the thin film SC;
wherein the second substrate covers the thin film SC and the control means.

Advantageously, the cathode layer may be made of indium-tin oxide, carbon nanostructures such as graphene or carbon nanotubes, metallic nanowires such as silver or copper, aluminum-doped zinc oxide, strontium vanadate SrVO₃ or any equivalent known by the skilled person in the art.

In the present description “organic” means any component comprising carbon and hydrogen, and which may further contain oxygen (O), nitrogen (N), phosphorus (P), sulfur (S), iron (Fe). Preferably, the organic component may be selected from Poly(9,9-bis(3′-(N,N-dimethyl)-N-ethylammonium-propyl-2,7-fluorene)-alt-2,7-(9,9-dioctylfluorene))dibromide (PFN-Br), le polyéthylèneimine (PEI), le PEIE, le Poly[(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylicdiimide (PDI-NO) ou le N,N′-Bis{3-[3-(Dimethylamino)propylamino]propyl}perylene-3,4,9,10-tetracarboxylicdiimide (PDINN) or any equivalent known by the skilled person in the art.

Advantageously, the metallic oxide-based nanoparticle may be selected from zinc oxide, aluminum-doped zinc oxide or any equivalent known by the skilled person in the art.

In the present description “conductive glue” means any conductive glue allowing the transfer of the electric energy. For example, the conductive glue may be silver-based glue, copper-based glue or any equivalent known by the skilled person in the art. For example, DELO-DUALBOND IC343 from Delo company (Germany).

In the present description “conductive” means any layer of a material allowing the transfer of the electric energy. The conductive may be made of any material known by the skilled person in the art for the transfer of electric energy, for example, it may be selected from printable ink comprising silver, aluminum, copper or any equivalent known by the skilled person in the art.

According to the present invention, the at least first and second substrates may be identical or different, with regard to the material of the substrate and/or the shape, preferably identical. Advantageously, the substrates may be made of glass. For example, they may be selected from glass made of monocrystalline silicon, LT-G000 Bare Glass from company Lumtec (Taiwan) or any equivalent known by the skilled person in the art. Advantageously, the substrates may be made of a polymer material, preferably polyethylene terephthalate (PET), polyethylene naphthalate (PEN), a mixture thereof or any equivalent known by the skilled person in the art. Advantageously, the PET may be have correct barrier properties, i.e. 10⁻² to 10⁻⁴ wvtr (water vapor transmission rate) at 25° C. The WVTR is a measure of the transfer of water vapor through a substance whose international unit is g/m²/day. For example, they may be selected from FTB3-50 from company 3M (United States of America) or any equivalent known by the skilled person in the art.

In the present description, “shape”, means the contour of one surface of the substrate. The skilled person understands the term “shape” to mean any shape suitable for its integration in any device. For example, the shape may be rectangular, square, triangular, oval, circular, trapezoidal, elliptical, hexagonal, pentagonal or octagonal.

Advantageously, the at least first and second substrates may have an area (length×width) from between 1 cm² and 1600 cm², preferably from between 1 cm² and 100 cm².

Advantageously, the at least first and second substrates may have a thickness from between 20 μm and 2 mm, preferably from between 50 μm and 1 mm.

Advantageously, the OPV module may have an area (length×width) from between 0.9 cm² and 1595 cm², preferably from between 0.9 cm² and 94 cm².

Advantageously, the OPV module may have a thickness from between 300 nm and 2 μm, preferably from between 500 nm and 1 μm.

Advantageously, the thin film SC may have an area (length×width) from between 0.9 cm² and 1595 cm², preferably from between 0.9 cm² and 94 cm².

Advantageously, the thin film SC may have a thickness from between 5 and 150 μm, preferably from between 15 and 60 μm.

Advantageously, the control means may have an area (length×width) from between 5 mm² and 25 cm², preferably from between 5 and 50 mm².

Advantageously, the control means may have a thickness from between 200 μm and 2 mm, preferably from between 400 μm and 1 mm.

Advantageously, the light energy storage device according to the invention can also comprise an external barrier glue which holds together the substrates positioned above and below of the OPV module(s) and/or thin film SC and control means stack.

In the present description “barrier glue” means any glue suitable for holding together the stack of substrates, OPV module(s) and/or thin film SC and control means. For example, the barrier glue may be selected from “DELO-KATIOBOND LP655” from company Delo (Germany) or any equivalent known by the skilled person in the art.

In the present description “lamination” means any technic known by the skilled person for manufacturing a device comprising multiple layers assembled together. To assemble the layers, this technic may use one or several of heat, pressure, welding and adhesive or glue. The adhesive or glue may be the barrier glue. For example, the lamination may be carried out by using a pouch laminator, a roll laminator or any equivalent device known by the skilled person in the art. For the purposes of the present invention, lamination is intended to protect mechanically and against moisture and oxygen the whole light energy storage device.

Advantageously, the light energy storage device according to the invention may comprise an OPV module or several OPV modules, identical or different, connected in series or parallel, each OPV module may comprise one or several OPV cells, preferably several, identical or different, for example two, three, four, five, six, etc. OPV cells.

Advantageously, the light energy storage device according to the invention may comprise a thin film supercapacitor (SC) or several thin film supercapacitors (SCs), identical or different, connected in series or parallel.

For example, the light energy storage device according to the invention may comprise an OPV module, a thin film SC and a control means printed on the same surface of a first substrate.

Advantageously, the light energy storage device according to the invention may comprise a conductive printed by inkjet printing, allowing the transfer of the electric energy generated by the OPV module to the thin film SC. This conductive may be printed on a surface of at least the first substrate of the at least first and second substrates.

For example, when the light energy storage device comprises an intermediate substrate, the light energy storage device may comprise successively: the first substrate, at least an OPV module, an intermediate substrate, and, next to each other, a thin film SC and a control means. The OPV module is therefore comprised between the first substrate and the intermediate substrate.

In the present description, “intermediate substrate”, means a substrate comprised between an OPV module on one side, and a thin film SC and a control means on the other side. The intermediate substrate may be identical or different to the first and/or second substrates, with regard to the material of the substrate and/or the shape.

Advantageously, the light energy storage device according to the invention may comprise a conductive, allowing the transfer of the electric energy generated by the OPV module to the thin film SC, printed on the same substrate surface as the OPV module and on the same substrate surface as the thin film SC and the control means.

The invention also relates to an apparatus comprising a light energy storage device according to the present description and a device using the electric energy generated by the OPV module and/or the electric energy stored in the thin film SC.

Advantageously, the apparatus according to the invention may comprise a device using the electric energy generated by the OPV module and/or the electric energy stored in the thin film SC, wherein the device using the electric energy is inside the said light energy storage device.

Advantageously, the apparatus according to the invention may comprise a device using the electric energy generated by the OPV module and/or the electric energy stored in the thin film SC, wherein the device using the electric energy is outside the said light energy storage device.

Advantageously, the device using the electric energy may comprise a thermic sensor, such as a sensor NXP NHS3100 from company NXP Semiconductors (Netherlands), a humidity sensor, pressure sensor, gas detection sensor or any equivalent known by the skilled person in the art.

Advantageously, the sensor may use a Near-Field Communication (NFC) protocol or any equivalent known by the skilled person in the art. Such protocols enable the skilled person to size the light energy storage device and therefore to select a light energy storage device enabling the sensor to operate. Indeed, such protocols provide all the information needed to estimate the energy requirements of the sensor and therefore a sensor may be used in many industrial tracking applications. A sensor may take measurement with the possibility to store the data internally and transmit it over low and mid-range distance.

For example, the device using the electric energy may comprise at least one NXP NHS3100 from company NXP Semiconductors (Netherlands) which is an IC optimized for temperature monitoring and logging Wireless & RF Integrated Circuits, (NFC/RFID); at least one “0402-5.6 pF” Multilayer ceramic capacitors MLCC—CMS “0402 5.6 pF” from company Murata Manufacturing (Japan); at least one Schottky barrier diode “PMEG2005EL” from company Murata Manufacturing (Japan) and at least one Flat Light Touch Switch “5.2×5.2” from company Mouser Electronics (United States of America).

Advantageously, when the device using the electric energy is inside the said light energy storage device, the device using the electric energy may be placed on the same surface of the substrate of the thin film SC.

The invention also relates to a process of manufacturing a light energy storage device according to the invention, said process comprising the following steps:
a) providing at least a first and a second substrates and optionally an intermediate substrate, made of glass or a polymer material,
b) printing by inkjet printing one OPV cell, on a surface of the first substrate, the OPV cell comprising:
   i) a transparent conductive cathode layer covering said surface of the first substrate,
   ii) a first interfacial metallic oxide-based nanoparticle or organic layer covering said cathode,
   iii) a photovoltaic active layer covering said first interfacial layer, and
   iv) a second interfacial layer comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of between 100 nm and 400 nm;
c) printing by inkjet printing, on the said surface of said first substrate or a surface of the intermediate substrate, a thin film SC;
d) printing by inkjet printing, on the same surface and substrate as the thin film SC, a conductive glue;
e) placing a control means allowing the transfer of the electric energy generated by the OPV module to the thin film SC, an electrically conductive material linking the OPV module and the thin film SC, on the printable glue;
f) printing by inkjet printing one conductive, allowing the transfer of the electric energy generated by the OPV module to the thin film SC, linking the OPV module, the thin film SC and the control means;
g) covering the thin film SC and the control means with the second substrate.

Advantageously, the printing steps of the process of manufacturing a light energy storage device according to the invention may be inkjet printed with the same printer. For example, the printer may be selected from Ceraprinter X-serie or F-serie both from Ceradrop—MGI Group (France) or any equivalent known by the skilled person in the art.

Advantageously, the process of manufacturing a light energy storage device according to the invention may further comprise a step of heat treatment. In the present description “heat treatment” means any step of heating a material, in a liquid or semi-liquid state, to evaporate the solvents comprised in the said material and/or to cure a material, for example a polymer, and/or to polymerize or cross-link polymerize a material, depending on the nature of said solvent or material. The light energy storage device may therefore undergo different heat treatments depending on the solvent(s), the duration of the treatment, the environment, the temperature, the presence of oxygen and the material(s) in presence to obtain the different layers. Preferably, for PET substrate, the heat treatment may be an annealing treatment, for example carried out at a temperature not exceeding 120° C. at the level of the substrate for a few minutes (no more than 10 min). Preferably, for PEN substrate, the heat treatment may be an annealing treatment, for example carried out at a temperature not exceeding 140° C. at the level of the substrate. Of course, the skilled person in the art is able to adapt the temperature of the heat treatment to the different layer to avoid any deformation or degradation of the different layers and/or substrates. The heat treatment may be carried out for example during a time between 1 and 10 minutes. For example, the heat treatment may be carried out by using a hotplate, convection oven, vacuum oven, heating lamp, preferably vacuum oven and more preferably under primary vacuum at the above indicated temperatures. It may also be a exposing the layers to some specific radiation such as infra-red (IR), near infra-red (NIR) or ultraviolet (UV; 350-400 nm). The light energy storage device may therefore be exposed to different radiations depending on the solvent(s), the duration of the treatment, the environment, the wavelength and the material(s) in presence to obtain the different layers.

In the present description “solvent” means any substance that is able to dissolve a material to obtain a solution. For example, the solvent may be selected from the group comprising water-based solvent such as water, alcohol-based solvent such as butanol, hexanol, 2-(4-Methylcyclohex-3-en-1-yl)propan-2-ol (terpineol), aromatic solvent such as 1,2-dimethylbenzene (o-xylene), 1,3,5-trimethylbenzene (mesitylene), 1,2,3,4-tetrahydronaphthalene (tetralin), 1-methylnaphthalene, 2-methylnaphthalene, 4-methoxybenzaldehyde (p-anisaldehyde), 2-methylanisole, diphenyl ether or any equivalent known by the skilled person in the art.

Advantageously, in the process of manufacturing a light energy storage device according to the invention, step b) may be carried out several times in order to obtain several cells.

Advantageously, in the process of manufacturing a light energy storage device according to the invention, step e) may be carried out using a pick and place technique. In the present description “pick and place technique” means pick the control means from a container comprising a stock of control means, and place the picked control means onto the printed glue. This “pick and place” technique” may be carried out manually or automatically by a machine able to carry out this technic. For example, the pick and place technique may be carried out after having inkjet-printed printable glue onto a substrate, through step d).

Advantageously, the pick and place technique may further comprise a heat treatment and/or an UV treatment to ensure the fixing of the control means by solidifying the conductive glue, for example by evaporation of the solvent and/or polymerizing and/or cross-linking and/or curing. In the present description “UV treatment” means an UV treatment able to polymerize and/or cross-link and/or cure the conductive glue. For example, the UV treatment may be carried out by using a wavelength from 352 to 405 nm (UV-A, spotting, deep polymerization, mechanical surface strength), depending on the conductive glue that is used to carry out the process of the present invention. The UV treatment may be carried out with an UV polymerisator, for example the device may be FireEdge UV LED curing lamp FE400 from Phoseon technology (United States of America). The time of the UV treatment may easily be determined by the skilled person from the knowledge of the power of the UV polymerisator and the conductive glue selected to carry out the process of the present invention, for example from 1 to 30 seconds.

Advantageously, the process of manufacturing a light energy storage device according to the invention may further comprise a step of placing a device using the electric energy generated by the OPV module and/or the electric energy stored in the thin film SC.

Advantageously, the device using the electric energy may be placed on the same substrate surface as the thin film SC.

Advantageously, in the process of manufacturing a light energy storage device according to the invention, step of placing a device using the electric energy may be carried out using a pick and place technique.

Advantageously, the process of manufacturing a light energy storage device according to the invention may further comprise a step of depositing the barrier glue which holds together the substrates positioned above and below of the OPV module(s) and/or thin film SC and control means stack.

For example, the process of manufacturing a light energy storage device according to the invention may comprise printing steps of an OPV module, for example as disclosed in document US202017787291, a thin film SC and a conductive glue on the same surface of the said first substrate.

Advantageously, the process of manufacturing a light energy storage device according to the invention may comprise a printing step of a conductive, allowing the transfer of the electric energy generated by the OPV module to the thin film SC, on the said surface of said first substrate.

For example, the process of manufacturing a light energy storage device according to the invention may comprise a printing step of an OPV module on a surface of a first substrate and printing steps of a thin film SC and a conductive glue on a surface of an intermediate substrate, wherein the OPV module is comprised between the said surface of the first substrate and a different surface of the intermediate substrate.

Advantageously, the process of manufacturing a light energy storage device according to the invention may comprise a printing step of a conductive, allowing the transfer of the electric energy generated by the OPV module to the thin film SC, on the said surface of said first substrate and on the said surface of the intermediate substrate.

Advantageously, a hole may be created by laser in the intermediate substrate at the level of the anode and cathode layers of the OPV module or a mechanical crimping of the anode and cathode layers of the OPV module can be achieved, to connect the OPV module to the other components (thin film SC and control means). To simplify the connection with the other components, the hole may be filled with a conductive material, preferably a conductive glue. Preferably, the hole may be created in a way that does not alter the transmission of light to the photovoltaic active layer, for example, at the side of the printed layers and without contact with them.

In the present description “mechanical crimping” means any operation making one or more conductive contacts between conductive layers separated by one or more non-conductive layers by means of at least one conductive metal spike, the at least one conductive metal spike penetrating the non-conductive layer(s) and contacting the conductive layers together via the at least one conductive metal spike. For example, the spike(s) may be selected from CrimpFlex contact from Nicomatic Group (France) or any equivalent known by the skilled person in the art. For example, metal spikes are used to contact together respectively the anodes of the OPV module layers, the cathodes of the OPV module layers, the control means and the thin film SC.

The invention relates to a process of manufacturing an apparatus comprising a light energy storage device according to the invention and a device using the electric energy generated by the OPV module and/or the electric energy stored in the thin film SC, the said process comprising:
a) a step of manufacturing a light energy storage device according to the invention; and
b) a step of connecting the manufactured light energy storage device to a device using the electric energy generated by the OPV module and/or the electric energy stored in the thin film SC.

While the invention has been described in detail herein in accord with certain preferred embodiments thereof, many modifications and changes therein may be effected by those skilled in the art. Accordingly, it is intended by the appended claims to cover all such modifications and changes as fall within the true spirit and scope of the invention. The present invention may further be understood by reference to the following description taken in connection with the accompanying drawings in which:

### BRIEF DESCRIPTION OF THE FIGURES

FIGS. 1a-1d represent[[s]] a light energy storage device according to the invention comprising an OPV module, a thin film SC and a control means (CM) printed on the same surface (su1) of a first substrate (S1).

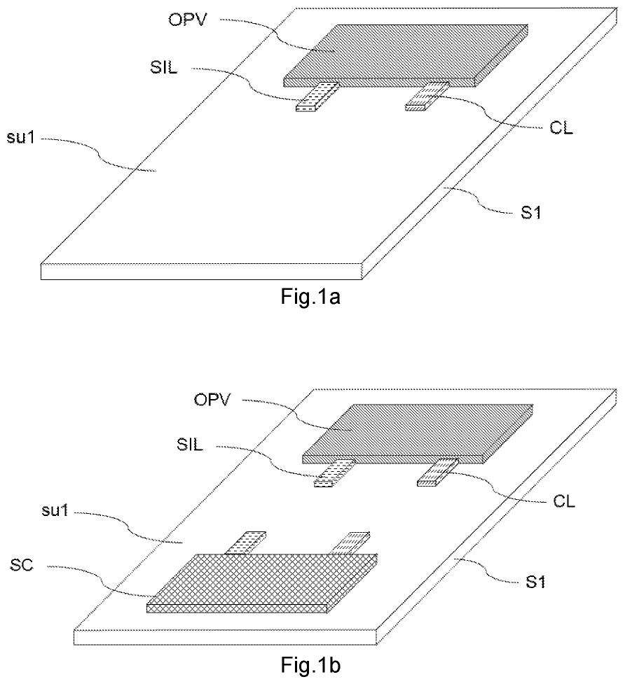

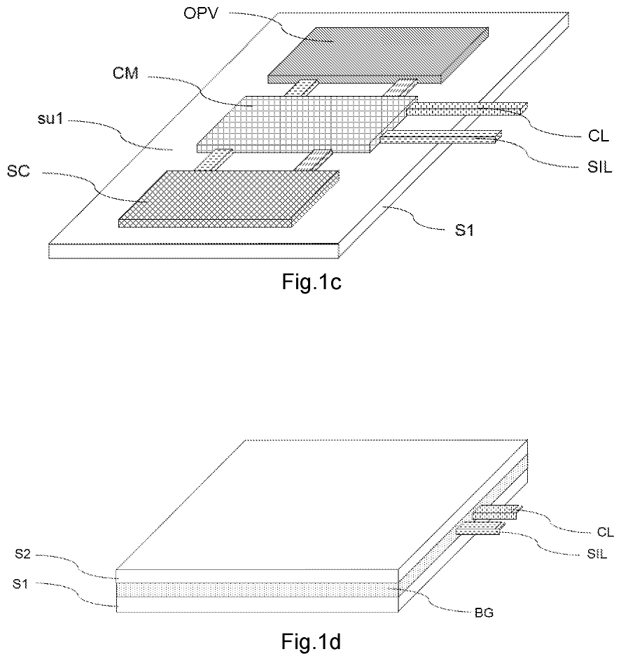

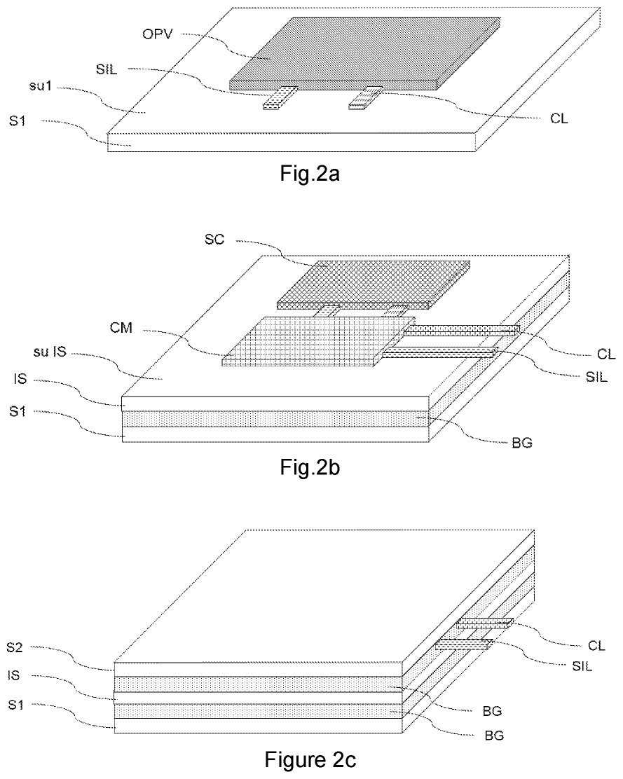

FIG. 1a represents:
a first substrate (S1) of polyethylene terephthalate (PET) having sufficient barrier properties; and
one OPV module (OPV) printed on a surface of the first substrate (S1) comprising a photovoltaic active layer that absorbs indoor light and convert it into electricity, a first interfacial layer that helps with charge extraction, a cathode layer (CL) and a second interfacial layer (SIL) that ensure the collection of photo-generated charge.

FIG. 1b represents FIG. 1a with the addition of:
thin film SC printed on the said surface (su1) of said first substrate (S1), by digital inkjet printing, wherein it is mainly printed in interdigital structure and composed by three layers: a current collector, an electrode, and an electrolyte.

FIG. 1c represents FIG. 1b with the addition of:
control means (CM), said control means (CM) being fixed on the said surface (su1) of said first substrate (S1) as the thin film SC with a conductive glue.

FIG. 1d represents FIG. 1c with the addition of:
a second substrate (S2) covering the thin film SC and the control means (CM); and
barrier glue (BG) encapsulating by lamination the OPV module, the thin film SC and the control means (CM).

FIGS. 2a-2c represent[[s]] a light energy storage device may comprise an OPV module printed on a surface (su1) of a first substrate (S1) with a thin film SC and a control means (CM) printed on a surface (su IS) of an intermediate substrate (IS), wherein the OPV module is comprised between the said surface (su1) of the first substrate (S1) and a different surface of the intermediate substrate (IS).

FIG. 2a represents:
a first substrate (S1) of polyethylene terephthalate (PET) having sufficient barrier properties; and
one OPV module printed on a surface (su1) of the first substrate (S1) comprising a photovoltaic active layer that absorbs indoor light and convert it into electricity, a first interfacial layer that helps with charge extraction, a cathode layer (CL) and a second interfacial layer (SIL) that ensure the collection of photo-generated charge.

FIG. 2b represents FIG. 2a with the addition of:
an intermediate substrate (IS) of polyethylene terephthalate (PET) having sufficient barrier properties;
barrier glue (BG) encapsulating by lamination the OPV module;
thin film SC printed on a surface (su IS) of the intermediate substrate (IS), by digital inkjet printing, wherein it is mainly printed in interdigital structure and composed by three layers: a current collector, an electrode and an electrolyte; and
control means (CM), said control means (CM) being fixed on the said surface (su IS) of the said intermediate substrate (IS) as the thin film SC with a conductive glue.

FIG. 2c represents FIG. 2b with the addition of:
a second substrate (S2) covering the thin film SC and the control means (CM); and
barrier glue (BR) encapsulating by lamination the thin film SC and the control means (CM).

### EXAMPLES

The following examples are not to be understood as limiting the scope of the present invention as defined herein and in the annexed claims.

### Example 1: Manufacture of a Thin Film Supercapacitor (SC)

In this example, a process of manufacturing a thin film supercapacitor is disclosed. This process comprises the following steps:
i) printing a first layer as a current collector by inkjet printing, wherein the first layer is made of silver (DM-SIJ-3200 from company Dycotec (United Kingdom));
ii) printing a second layer as an electrode by inkjet printing, wherein the second layer is made of carbon black (JR-700HV from company Novacentrix (United States of America));
iii) printing a third layer as an electrolyte by inkjet printing according to the following publication: Jeong, Jaehoon; Marques, Gabriel Cadilha; Feng, Xiaowei; Boll, Dominic; Singaraju, Surya Abhishek; Aghassi-Hagmann, Jasmin; Hahn, Horst; Breitung, Ben (2019). Ink-Jet Printable, Self-Assembled, and Chemically Crosslinked Ion-Gel as Electrolyte for Thin Film, Printable Transistors. Advanced Materials Interfaces, 1901074-. doi:10.1002/admi.201901074)).

The printing steps were carried out to obtain the layer by using a Cera printer X-serie from Ceradrop—MGI Group (France). To reach the following thicknesses, a multi-pass technic is used for the different printed layers. The multi pass technics is well known by the skilled person in the art. It is consisting of apply several printing passages in order to obtain the desired layer thickness. It depends on the device used to print the different layers and the composition of the material used to print the layers.

The printed layers are in a liquid or semi-liquid state. The heat treatment allows the evaporation of the residual solvents and thus to obtain thin layers, with a thickness of to 20 μm. The heat treatment for the first layer is an annealing treatment carried out at a temperature of vacuum oven of 160-170° C., for a time of 8-12 minutes, which leads to a temperature preferably not exceeding 120° C. at the level of the substrate.

The heat treatment for the second layer is an annealing treatment carried out at a temperature of 160-170° C., for a time of 8-12 minutes, which leads to a temperature preferably not exceeding 120° C. at the level of the substrate.

The UV treatment for the third layer is carried out at a wavelength 390-400 nm in order to obtain an ionogel structure, in the present example, for a time of 30 seconds to 2 minutes. We thus have obtained an ionogel layer with the desired mechanical aspect (i.e. gel) without altering the electrical properties of the ionogel.

Different thicknesses of the different layers have been printed in this example:
The first layer has been printed with thicknesses of from 5 to 20 μm.
The second layer has been printed with thicknesses of from 5 to 20 μm.
The third layer has been printed with thicknesses of from 5 to 20 μm.

The thin film supercapacitor (SC) obtained in this example measures 48 mm×34 mm×60 μm (L×W×T—Length×Width×Thickness).

Two thin film supercapacitors (SC) obtained in this example have been connected in parallel. The capacity of both thin film supercapacitors is 60 mF and their energy density is comprised between 30 and 120 μWh·cm⁻² with a maximum voltage window between 1.9 and 2.7 V.

### Example 2: Manufacture of a Light Energy Storage Device Exempt of an Intermediate Substrate (IS)

Firstly, a first substrate (S1) made of PET and having sufficient barrier properties is provided.

Secondly, one OPV module is printed on a surface (su1) of the said first substrate (S1) (see FIG. 1a). The said OPV module comprises five OPV cells connected in series comprising:
i) a cathode layer (CL) of indium-tin oxide covering said surface (su1) of the first substrate (S1),
ii) a first interfacial layer of aluminum-doped zinc oxide, said first interfacial layer covering said cathode,
iii) a photovoltaic active layer covering said first interfacial layer, and
iv) a second interfacial layer (SIL) comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of 350 nm.

The complete manufacturing process used in this example for this OPV module is described in U.S. patent application Ser. No. 17/787,291 (US phase of PCT/FR2020/052623).

The above OPV module measures 60×25×0.3 mm³ (L×W×T) and performs as follows when exposed to a light intensity of 500 and 1000 lux.

TABLE 1
performance of the OPV module obtained in Example 2

| | Open | Short | | Maximal | |
|---|---|---|---|---|---|
| | circuit | circuit | Maximal | intensity | Maximal |
| Light intensity | voltage | intensity | voltage | of current | Power |
| (lux) | V_{oc} (V) | I_{sc} (μA) | Vₘₐₓ (V) | Iₘₐₓ (μA) | Pₘₐₓ (μW) |
| 1000 | 3.1 | 153 | 2.4 | 125 | 297 |
| 500 | 3 | 81 | 2.4 | 66 | 156 |

The photovoltaic active layer absorbs indoor light and convert it into electricity, the interfacial layer helps with charge extraction and two electrodes ensures the collection of photo-generated charge. All layers are inkjet printed with the same printer as in Example 1.

Thirdly, two thin film SC according to Example 1 are inkjet printed on the said surface (su1) of said first substrate (S1) (see FIG. 1b) and connected in parallel.

The penultimate step consists in fixing a control means (CM) and a device using the electric energy generated by the OPV module and/or the electric energy stored in the thin film SC on the said surface (su1) of the first substrate (S1) as the thin film SC with a conductive glue “DELO-DUALBOND IC343” from company Delo (Germany) (see FIG. 1c). The control means is a control means PMIC AEM10941 (commercial reference) from company E-peas (Belgium) and the device using the electric energy comprises a NXP NHS3100 from NXP Semiconductors (Netherlands) which is an IC optimized for temperature monitoring and logging Wireless & RF Integrated Circuits, (NFC/RFID); two “0402-5.6 pF” Multilayer ceramic capacitors MLCC—CMS “0402 5.6 pF” from Murata Manufacturing (Japan): two Schottky barrier diode “PMEG2005EL” from Murata Manufacturing (Japan) and a Flat Light Touch Switch “5.2×5.2” from Mouser Electronics (United States of America).

The control means (MS) makes the link between the two devices (OPV module and thin film SC). The connection between this control means (MS) and the other devices (OPV module and thin film SC) is made by inkjet printing of a conductive on the first substrate. The conductive is made of silver.

The last step is a step of depositing a barrier glue (BG) which holds together the first substrate (S1) and a second substrate (S2) positioned above and below of the OPV module and/or thin film SC and control means stack. This step produces the following stack: first substrate (S1)—OPV module (OPV), thin film SC (SC) and control means (CM)—second substrate (S2) (see FIG. 1d). The barrier glue is a barrier glue “DELO-KATIOBOND LP655” from company Delo (Germany).

Several all-printed light energy storage devices (except for the control means) have been manufactured using the process disclosed in this example, with different dimensions, for example small dimensions of 30 mm×40 mm×1 to 3 mm. All manufactured devices proved functional, including under indoor light (200 to 1,000 lux) (see example 6 describing a temperature sensor connected to a light energy storage device obtained by the process disclosed in example 2 and an interface).

These several light energy storage devices comprise an autonomous electric temperature sensor. Therefore, in this example, the light energy storage devices store light energy and measure the temperature, but the concept can be adapted on any other physical parameter like humidity, pressure, gas detection, only the storage element and the OPV need to be adjusted for each case.

### Example 3: Manufacture of a Light Energy Storage Device Comprising an Intermediate Substrate (IS)

This example is similar to example 2: printing an OPV module, printing a thin film SC and integrating a control means. The major difference lies in the way the three components are associated.

Firstly, a first substrate (S1) made of PET and having sufficient barrier properties is provided.

Secondly, one OPV module is printed on a surface (su1) of the said first substrate (S1) (see FIG. 2a). The said OPV module comprises five OPV cells connected in series comprising:
v) a cathode layer (CL) of indium-tin oxide covering said surface (su1) of the first substrate (S1),
vi) a first interfacial layer of aluminum-doped zinc oxide, said first interfacial layer covering said cathode,
vii) a photovoltaic active layer covering said first interfacial layer, and
viii) a second interfacial layer (SIL) comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of 350 nm.

The complete manufacturing process used for this OPV module is described in U.S. patent application Ser. No. 17/787,291 (US phase of PCT/FR2020/052623).

The OPV module of this example has the same dimensions and performances as the OPV module described in Example 2.

The photovoltaic active layer absorbs indoor light and convert it into electricity, the interfacial layer helps with charge extraction and two electrodes (SIL and CL) ensures the collection of photo-generated charge. All layers are inkjet printed with the same printer as in Example 2.

This time, the step of depositing a barrier glue (BG) involves the first substrate (S1) and an intermediate substrate (IS) positioned above and below of the OPV module (OPV). This step produces the following stack: first substrate (S1)—OPV module (OPV)—intermediate substrate (IS) (see FIG. 2b). The barrier glue is the same as in Example 2.

The said stack is encapsulated in barrier film “FTB3-50” from 3M (United States of America).

Two holes were created by laser on the second barrier film at the level of the anode and cathode layers of the OPV module to allow the connection of the OPV module to the other components (thin film SC and control means). To simplify the connection with the other components, the holes were be filled with a conductive glue “DELO-DUALBOND IC343” from company Delo (Germany).

Thirdly, two thin film SC according to Example 1 are inkjet printed on a surface (su IS) of said intermediate substrate (IS) covered by the barrier film and connected in parallel.

The penultimate step consists in fixing a control means (CM) and a device using the electric energy generated by the OPV module and/or the electric energy stored in the thin film SC on the said surface (su IS) of the intermediate substrate (IS) as the thin film SC with a conductive glue “DELO-DUALBOND IC343” from company Delo (Germany) (see FIG. 2b). The control means, the device using the electric energy and the pick and place technique are the same as in Example 2.

The control means (MS) makes the link between the two devices (OPV module and thin film SC). The connection between this control means (MS) and the other devices (OPV module and thin film SC) is made by inkjet printing of a conductive. The conductive is the same as in Example 2.

The last step is a step a step of depositing a barrier glue (BG) “FTB3-50” from 3M (United States of America) which holds together the intermediate substrate (IS) and a second substrate (S2) positioned above and below of the thin film SC (SC) and control means (CM). This step produces the following stack: first substrate (S1)—OPV module (OPV)—intermediate substrate (IS)—thin film SC (SC) and control means (CM)—second substrate (S2) (see FIG. 2c).

Several all-printed light energy storage devices (except for the control means) have also been manufactured using the process disclosed in this example, with different dimensions, for example small dimensions of 30 mm×40 mm×1 to 3.5 mm. All manufactured devices proved functional, including under indoor light (200 to 1,000 lux).

These several light energy storage devices comprise an autonomous electric temperature sensor. Therefore, in this example, the light energy storage devices store light energy and measure the temperature, but the concept can be adapted on any other physical parameter like humidity, pressure, gas detection, only the storage element and the OPV need to be adjusted for each case.

While the invention has been particularly shown and described with reference to preferred embodiments thereof, it will be understood by those skilled in the art that various changes in form and detail may be made without departing from the spirit and scope of the invention.

### REFERENCES

1. US patent application US202017787291 (US phase of PCT/FR2020/052623).
2. ECS Transactions, 2018, 86 (14) 163-178. doi: 10.1149/08614.0163ecst.
3. the Journal of Power Sources, 330, 2016, 92-103. doi:10.1016/j.jpowsour.2016.08.14.
4. Jeong, Jaehoon et al., Ink-Jet Printable, Self-Assembled, and Chemically Crosslinked Ion-Gel as Electrolyte for Thin Film, Printable Transistors. Advanced Materials Interfaces. 2019, 1901074. doi:10.1002/admi.201901074.
5. Delannoy, P.-E. et al., 2015, Toward fast and cost-effective ink-jet printing of solid electrolyte for lithium microbatteries. Journal of Power Sources. 2015, 274, 1085-1090. doi:10.1016/j.jpowsour.2014.10.164.

1. A light energy storage device comprising an organic photovoltaic (OPV) module and a thin film supercapacitor (SC) for the storage of an electric energy generated by the OPV module, said device comprising:
a) at least a first and a second substrates (S1, S2) and optionally an intermediate substrate (IS), made of glass or a polymer material,
b) one OPV module comprising, on a surface (su1) of the first substrate S1, one OPV cell, said OPV cell comprising:
i) a transparent conductive cathode layer (CL) covering said surface (su1) of the first substrate (S1),
ii) a first interfacial metallic oxide-based nanoparticle or organic layer covering said cathode,
iii) a photovoltaic active layer covering said first interfacial layer, and
iv) a second interfacial layer (SIL) comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of between 100 nm and 400 nm;
wherein each layer i) to iv) being printed by inkjet printing;
c) a thin film SC printed on the said surface (su1) of said first substrate (S1) or on a surface (su IS) of the intermediate substrate (IS), by digital inkjet printing;
d) a control means (CM), said control means being fixed on the same surface (su1 or su IS) and substrate (S1 or IS) as the thin film SC with a conductive glue; and
e) one conductive printed by inkjet printing and linking the OPV module, the thin film SC and the control means, and allowing the transfer of the electric energy generated by the OPV module to the thin film SC;
wherein the second substrate (S2) covers the thin film SC and the control means.

2. A light energy storage device according to claim 1, wherein the conductive glue is silver-based glue, copper-based glue or any equivalent known by the skilled person in the art.

3. A light energy storage device according to claim 1, wherein the at least a first and a second substrates are identical or different.

4. A light energy storage device according to claim 1, wherein the light energy storage device further comprises an external barrier glue which holds together the substrates positioned above and below of the OPV module and/or thin film SC and control means stack.

5. A light energy storage device according to claim 1, wherein the light energy storage device comprises an OPV module or several OPV modules, identical or different, each OPV module comprises one or several OPV cells.

6. A light energy storage device according to claim 1, wherein the light energy storage device comprises an OPV module, a thin film SC and a control means printed on the same surface of the first substrate.

7. A light energy storage device according to claim 1, wherein the light energy storage device comprises an intermediate substrate, and wherein the light energy storage device comprises successively: the first substrate, at least an OPV module, an intermediate substrate, and, next to each other, a thin film SC and a control means.

8. A light energy storage device according to claim 1, wherein the light energy storage device comprises a conductive, allowing the transfer of the electric energy generated by the OPV module to the thin film SC, printed on the same substrate surface as the OPV module and on the same substrate surface as the thin film SC and the control means.

9. A process of manufacturing a light energy storage device according to claim 1, said process comprising the following steps:
a) providing at least a first and a second substrates (S1, S2) and optionally an intermediate substrate (IS), made of glass or a polymer material,
b) printing by inkjet printing one OPV cell, on a surface (su1) of the first substrate (S1), the OPV cell comprising:
i) a transparent conductive cathode layer (CL) covering said surface (su1) of the first substrate (S1),
ii) a first interfacial metallic oxide-based nanoparticle or organic layer covering said cathode,
iii) a photovoltaic active layer covering said first interfacial layer, and
iv) a second interfacial layer (SIL) comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of between 100 nm and 400 nm;
c) printing by inkjet printing, on the said surface (su1) of said first substrate (S1) or on a surface (su IS) of the intermediate substrate (IS), a thin film SC;
d) printing by inkjet printing, on the same surface (su1 or su IS) and substrate (S1 ou IS) as the thin film SC, a conductive glue;
e) placing a control means (CM) allowing the transfer of the electric energy generated by the OPV module to the thin film SC, an electrically conductive material linking the OPV module and the thin film SC, on the printable glue;
f) printing by inkjet printing one conductive, allowing the transfer of the electric energy generated by the OPV module to the thin film SC, linking the OPV module, the thin film SC and the control means;
g) covering the thin film SC and the control means with the second substrate (S2).

10. A process according to claim 9, wherein the process further comprises a step of heat treatment.

11. A process according to claim 9, wherein step b) is carried out several times in order to obtain several cells.

12. A process according to claim 9, wherein step e) is carried out using a pick and place technique.

13. An apparatus comprising a light energy storage device according to claim 1 and a device using the electric energy generated by the OPV module and/or the electric energy stored in the thin film SC.

14. A process of manufacturing an apparatus according to claim 13, the said process comprising:
a step of manufacturing a light energy storage device according to the invention; and
a step of connecting the manufactured light energy storage device to a device using the electric energy generated by the OPV module and/or the electric energy stored in the thin film SC.
